(19) United States
(12) Patent Application Publication
(10) Pub. No.: US 2026/0332143 A1
(43) Pub. Date: Oct. 22, 2026

(54) DRIVER CIRCUIT FOR HIGH-SIDE TRANSISTOR

(71) Applicant: ROHM CO., LTD., Kyoto (JP)

(72) Inventors: Yuichi SHINOZAKI, Kyoto (JP); Taketo TSUKASA, Kyoto (JP)

(21) Appl. No.: 19/704,481

(22) Filed: Jun. 11, 2026

Related U.S. Application Data
(63) Continuation of application No. PCT/JP2024/043209, filed on Dec. 6, 2024.

(30) Foreign Application Priority Data
Dec. 12, 2023 (JP) 2023-209190

(51) Int. Cl. H03K 17/687; H02M 1/08; H02M 3/158; H03K 19/0185

(52) U.S. Cl. CPC H03K 17/687; H02M 1/08; H02M 3/1588; H03K 19/018521; H03K 2217/0063; H03K 2217/0072

(57) ABSTRACT

A level shift circuit level-shifts an input signal and supplies it to a high-side driver. A first transistor and a second transistor constitute a latch circuit. A seventh transistor is connected between a first node and a ground line, and an eighth transistor is connected between a second node and the ground line. A logic circuit is configured to turn on a pair of a fifth transistor and the seventh transistor when the input signal is at a high level, and turn on a pair of a sixth transistor and the eighth transistor when the input signal is at a low level.

### BACKGROUND

### 1. Technical Field

The present disclosure relates to a driver circuit for a high-side transistor.

### 2. Description of Related Art

In various applications such as DC/DC converters, power converters, and motor driver circuits, a switching circuit including a power transistor and a driver circuit thereof (gate driver circuit) is used.

FIG. 1 is a circuit diagram of a switching circuit. The switching circuit 100R includes a high-side transistor MH, a low-side transistor ML, a high-side driver circuit 200R, and a low-side driver circuit 110.

The high-side transistor MH is provided between an input terminal (or an input line) IN and a switching terminal (or a switching line) VS, and the low-side transistor ML is provided between the switching terminal VS and a ground terminal GND. The high-side driver circuit 200R drives the high-side transistor MH according to a control input HIN, and the low-side driver circuit 110 drives the low-side transistor ML according to a control input LIN.

When the high-side transistor MH is turned on and the low-side transistor ML is turned off, an input voltage V_{IN} is generated at the switching terminal VS, and when the high-side transistor MH is turned off and the low-side transistor ML is turned on, a ground voltage V_{GND} (0 V) is generated at the switching terminal VS. During a period in which both the high-side transistor MH and the low-side transistor ML are turned off, the switching terminal VS is in a high-impedance state. The switching circuit 100R supplies power to a load (not shown) by switching among these three states.

An N-type (N-channel) transistor may be used as the high-side transistor MH. In order to turn on the high-side transistor MH and maintain the on-state, it is necessary to apply a voltage exceeding a gate threshold V_{GS(th)} of a field-effect transistor (FET) between its gate and source. When the high-side transistor MH is turned on, a voltage V_{S} of the switching line VS, that is, a source voltage of the high-side transistor MH, is substantially equal to the input voltage V_{IN}. Therefore, in order to maintain the on-state of the high-side transistor MH, it is necessary to apply a gate signal higher than V_{IN}+V_{GS(th)} to the gate of the high-side transistor MH.

A bootstrap circuit is provided to generate a gate signal higher than the input voltage V_{IN}. The bootstrap circuit includes a bootstrap capacitor C_{BST} and a rectifying element D1. The bootstrap capacitor C_{BST} is provided between a bootstrap terminal (or a bootstrap line) VB and the switching terminal VS. A DC voltage V_{REG} (>V_{GS(th)}) is applied to the bootstrap terminal VB via the rectifying element D1.

When a switching voltage V_{S} is low (0 V), a capacitor C_{BST} is charged via a rectifying element D1, and its voltage across both ends becomes ΔV=V_{REG}−Vf. Vf is a voltage drop of the rectifying element D1. When the switching voltage V_{S} rises, a voltage V_{B} of a bootstrap terminal VB rises while maintaining V_{B}=V_{S}+ΔV. A potential difference between the VB terminal and the VS terminal is maintained at ΔV by a bootstrap circuit.

A high-side driver circuit 200R includes a buffer (driver) 210 and a level shift circuit 220. A voltage V_{B} is supplied to an upper power supply terminal of the buffer 210, and a voltage V_{S} is supplied to a lower power supply terminal thereof. The buffer 210 supplies a gate voltage, with V_{B} being high and V_{S} being low, to a gate of a high-side transistor MH.

The level shift circuit 220 converts a binary control signal HIN of a logic level (V_{DD}/0V) into a binary intermediate signal LVSFTOUT of (V_{B}/V_{S}). If a voltage drop of a diode D1 is neglected, V_{B} is approximately equal to V_{S}+V_{REG}, and thus an amplitude of an output LVSFTOUT of the level shift circuit 220 becomes V_{REG}.

In an application where an input voltage V_{IN} is several tens of volts or more, or 100 V or more, a P-channel MOSFET having a double-diffused MOS (DMOS) structure with a high withstand voltage is used for a level shift circuit. In this configuration, a low level of the output LVSFTOUT of the level shift circuit 220 becomes V_{S}+V_{GS(th)}, and the amplitude of the output LVSFTOUT of the level shift circuit 220 is narrowed to V_{REG}−V_{GS(th)}. V_{GS(th)} is a gate-to-source threshold voltage of the P-channel MOSFET. Therefore, there is a problem that circuit operation becomes unstable when a DC voltage V_{REG} decreases.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures.

FIG. 1 is a circuit diagram of a switching circuit.

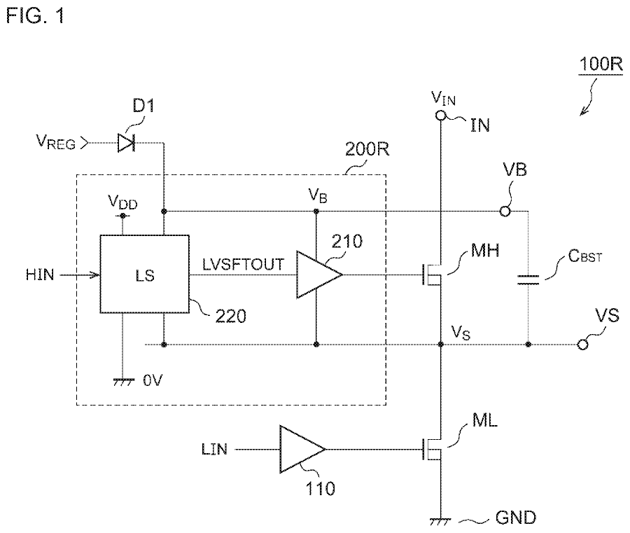

FIG. 2 is a circuit diagram of a switching circuit according to an embodiment.

FIG. 3 is an operation waveform diagram of the driver circuit of FIG. 2.

FIG. 4 is a circuit diagram of a level shift circuit according to Modification 1.

FIG. 5 is a circuit diagram of a level shift circuit according to Modification 2.

FIG. 6 is a circuit diagram of a level shift circuit according to Modification 3.

FIG. 7 is a circuit diagram of a controller circuit of a DC/DC converter.

FIG. 8 is a circuit diagram of an inverter apparatus including a driver circuit.

### DETAILED DESCRIPTION

### Outline of Embodiments

An overview of several exemplary embodiments of the present disclosure will be described. This overview simplifies and describes several concepts of one or more embodiments for the purpose of a basic understanding of the embodiments as a preface to the detailed description described later, and does not limit the breadth of the disclosure. This overview is not a comprehensive overview of all possible embodiments, and is not intended to identify key elements of all embodiments or to delineate the scope of some or all aspects. For convenience, “one embodiment” may be used to refer to a single embodiment (example or modification) or a plurality of embodiments (examples or modifications) disclosed in the present specification.

A driver circuit according to an embodiment drives an N-type high-side transistor connected between an input line and a switching line. The driver circuit includes a level shift circuit configured to level-shift an input signal, and a high-side driver configured to drive the high-side transistor according to an output of the level shift circuit. The level shift circuit includes: a P-type first transistor connected between a bootstrap line and a first node; a P-type second transistor connected between the bootstrap line and a second node, the P-type second transistor being cross-coupled with the first transistor; a P-type third transistor that is a high-voltage element, having a gate connected to the switching line and a source connected to the first node; a P-type fourth transistor that is a high-voltage element, having a gate connected to the switching line and a source connected to the second node; an N-type fifth transistor connected between a drain of the third transistor and a ground line; an N-type sixth transistor connected between a drain of the fourth transistor and the ground line; an N-type seventh transistor that is a high-voltage element connected between the first node and the ground line; an N-type eighth transistor that is a high-voltage element connected between the second node and the ground line; a logic circuit configured (i) to turn on a pair of the fifth transistor and the seventh transistor when the input signal is at a high level, and (ii) to turn on a pair of the sixth transistor and the eighth transistor when the input signal is at a low level; and a first assist circuit configured (i) to source a first assist current to the second node in accordance with a first pulse signal based on a positive edge of the input signal entering the high level from the low level, and (ii) to source a second assist current to the first node in response to a second pulse signal based on a negative edge of the input signal entering the low level from the high level.

According to this configuration, by injecting the assist current to the first node or the second node by the first assist circuit, a current caused by parasitic capacitance can be canceled. Thereby, a state transition of a latch circuit including the cross-coupled first transistor and second transistor can be accelerated, and the level shift circuit can transmit the input signal to the high-side driver at high speed. Further, in a state where the seventh transistor is turned on, by drawing a current from the first node toward the ground, a voltage of the first node can be lowered to near a voltage of the switching line. Similarly, in a state where the eighth transistor is turned on, by drawing a current from the second node toward the ground, a voltage of the second node can be lowered to near the voltage of the switching line. Thereby, amplitudes of signals generated at the first node and the second node can be widened, and stability of the circuit when a potential difference between the bootstrap line and the switching line becomes small can be enhanced.

In one embodiment, the level shift circuit may further include a first resistor connected in series with the seventh transistor between the first node and the ground line, and a second resistor connected in series with the eighth transistor between the second node and the ground line. By providing the first resistor and the second resistor, an amount of steady-state current flowing via the seventh transistor and the eighth transistor can be reduced, and a decrease in efficiency can be suppressed.

In one embodiment, the first assist circuit may include: an N-type ninth transistor that is a high-voltage element, having a gate configured to receive the first pulse signal; an N-type tenth transistor that is a high-voltage element, having a gate configured to receive the second pulse signal; a first current mirror circuit configured to mirror a current flowing through the ninth transistor to generate the first assist current; and a second current mirror circuit configured to mirror a current flowing through the tenth transistor to generate the second assist current.

In one embodiment, the level shift circuit may further include a second assist circuit configured (i) to sink a third assist current from the first node in accordance with the first pulse signal, and (ii) to sink a fourth assist current from the second node in response to the second pulse signal. By the second assist circuit, the state transition of the latch circuit including the cross-coupled first transistor and second transistor can be further accelerated.

In one embodiment, the second assist circuit may include: an N-type eleventh transistor that is a high-voltage element, having a gate configured to receive the first pulse signal and a drain connected to the first node; and an N-type twelfth transistor that is a high-voltage element, having a gate configured to receive the second pulse signal and a drain connected to the second node.

In one embodiment, the level shift circuit may further include a third assist circuit configured (i) to source a fifth assist current to the second node when the input signal is at the high level, and (ii) to source a sixth assist current to the first node when the input signal is at the low level. By the third assist circuit, when a state of the latch circuit including the first transistor and the second transistor is erroneously inverted, the state can be restored.

In one embodiment, the third assist circuit may include: an N-type thirteenth transistor that is a high-voltage element configured to turn on when the input signal is at the high level; an N-type fourteenth transistor that is a high-voltage element configured to turn on when the input signal is at the low level; a third current mirror circuit configured to mirror a current flowing through the thirteenth transistor to generate the fifth assist current; and a fourth current mirror circuit configured to mirror a current flowing through the fourteenth transistor to generate the sixth assist current.

A switching circuit according to an embodiment may include: a high-side transistor provided between an input line and a switching line; a low-side transistor provided between the switching line and a ground line; and the above-described driver circuit configured to drive the high-side transistor.

A controller circuit for a DC/DC converter according to an embodiment may include: a pulse modulator configured to generate a pulse signal such that an output of the DC/DC converter approaches a target; and the above-described driver circuit configured to drive an N-type high-side transistor based on the pulse signal.

### EMBODIMENTS

Hereinafter, preferred embodiments will be described with reference to the drawings. The same or equivalent constituent elements, members, and processes shown in the respective drawings are denoted by the same reference numerals, and redundant description thereof will be omitted as appropriate. Further, the embodiments are illustrative and do not limit the disclosure, and all features or combinations thereof described in the embodiments are not necessarily essential to the disclosure.

In the present specification, “a state where a member A is connected to a member B” includes not only a case where the member A and the member B are physically and directly connected, but also a case where the member A and the member B are indirectly connected via another member that does not substantially affect their electrical connection state or does not impair functions and effects achieved by their coupling.

Similarly, “a state where a member C is provided between a member A and a member B” includes not only a case where the member A and the member C, or the member B and the member C are directly connected, but also a case where they are indirectly connected via another member that does not substantially affect their electrical connection state or does not impair functions and effects achieved by their coupling.

Further, “a signal A (voltage, current) is in accordance with a signal B (voltage, current)” means that the signal A correlates with the signal B. Specifically, it means a case where (i) the signal A is the signal B, (ii) the signal A is proportional to the signal B, (iii) the signal A is obtained by level-shifting the signal B, (iv) the signal A is obtained by amplifying the signal B, (v) the signal A is obtained by inverting the signal B, (vi) or any combination thereof, or the like. Those skilled in the art understand that a range of “being in accordance with” is determined according to types and purposes of the signals A and B.

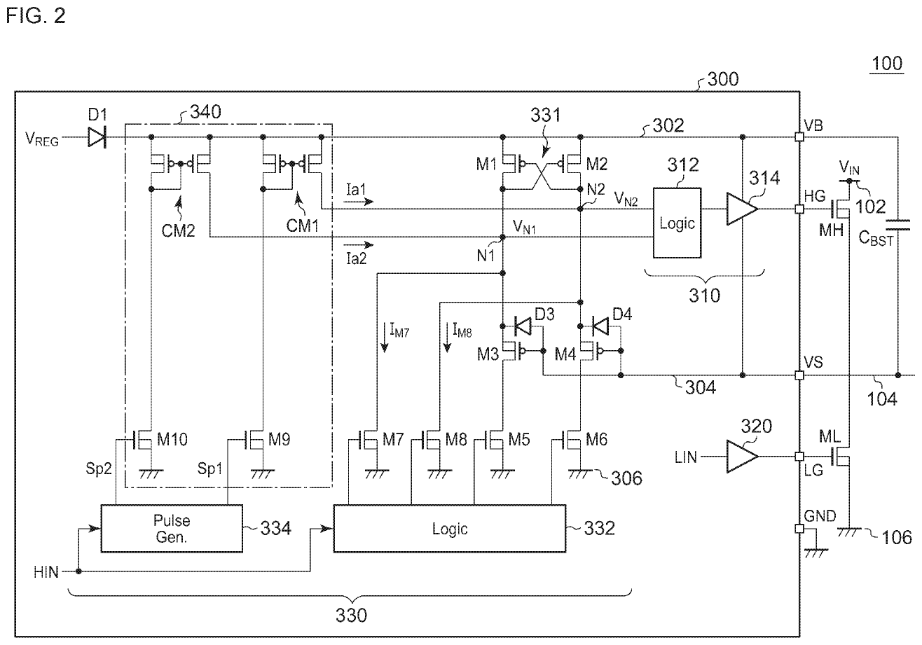

FIG. 2 is a circuit diagram of a switching circuit 100 according to one embodiment. The switching circuit 100 mainly includes a high-side transistor MH, a low-side transistor ML, and a driver circuit 300. The driver circuit 300 is an integrated circuit (IC) in which constituent elements are integrated on a semiconductor chip.

The high-side transistor MH is an N-channel type or an NPN type (collectively referred to as an N-type), and is provided between an input line 102 and a switching line 104. The low-side transistor ML is of the same type as the high-side transistor MH, and is connected between the switching line 104 and a ground line. An input voltage V_{IN} exceeding several tens of volts to 100 V is supplied to the input line 102.

The driver circuit 300 drives the high-side transistor MH and the low-side transistor ML. The driver circuit 300 includes a bootstrap pin VB, a high-side gate pin HG, a switching pin VS, a low-side gate pin LG, and a ground pin GND. A bootstrap capacitor C_{BST} is externally connected between the bootstrap pin VB and the switching pin VS. Further, the high-side gate pin HG is connected to a gate of the high-side transistor MH, and the low-side gate pin LG is connected to a gate of the low-side transistor ML.

The driver circuit 300 includes a bootstrap line 302, a switching line 304, a high-side driver 310, a low-side driver 320, a level shift circuit 330, and a rectifying element D1.

The bootstrap line 302 is connected to the bootstrap pin VB, and the switching line 304 is connected to the switching pin VS. A DC voltage V_{REG} stabilized to a predetermined voltage level is applied to the bootstrap line 302 via the rectifying element D1. For example, this DC voltage V_{REG} may be a power supply voltage V_{DD} of about 5 V. The rectifying element D1 may be a diode, or may be a switch whose on and off are switched in conjunction with switching of the switching circuit 100.

The high-side driver 310 drives the high-side transistor MH according to an input signal HIN. The input signal HIN is a binary signal having the power supply voltage V_{DD} as a high level and a ground voltage (0 V) as a low level. In one embodiment, when the input signal HIN is high, the high-side transistor MH is turned on, and when the input signal HIN is low, the high-side transistor MH is turned off. Similarly, the low-side driver 320 drives the low-side transistor ML according to an input signal LIN.

The level shift circuit 330 level-shifts the input signal HIN and supplies it to the high-side driver 310. The high-side driver 310 drives the high-side transistor MH according to an output of the level shift circuit 330. The high-side driver 310 includes a logic circuit 312 and a buffer 314. The logic circuit 312 controls a state of the buffer 314 based on output signals V_{N1} and V_{N2} of the level shift circuit 330.

The level shift circuit 330 includes a first transistor M1, a second transistor M2, a third transistor M3, a fourth transistor M4, a fifth transistor M5, a sixth transistor M6, a seventh transistor M7, an eighth transistor M8, a first assist circuit 340, a logic circuit 332, and a pulse generator 334.

The first transistor M1 and the second transistor M2 are P-channel MOSFETs, are cross-coupled, and constitute a latch circuit 331. Sources of the first transistor M1 and the second transistor M2 are connected to the bootstrap line 302. A drain of the first transistor M1 and a gate of the second transistor M2 are connected to a first node N1. A drain of the second transistor M2 and a gate of the first transistor M1 are connected to a second node N2. The first node N1 and the second node N2 are output nodes of the level shift circuit 330, and respective voltages V_{N1} and V_{N2} are output signals of the level shift circuit 330.

The third transistor M3 and the fourth transistor M4 are P-channel MOSFETs that are high-voltage elements. Gates of the third transistor M3 and the fourth transistor M4 are connected to the switching line 304. Further, a source of the third transistor M3 is connected to the first node N1, and a source of the fourth transistor M4 is connected to the second node N2. A diode D3 is connected between the gate and source of the third transistor M3, and a diode D4 is connected between the gate and source of the fourth transistor M4.

As the high-voltage element, a transistor having a double-diffused MOS (DMOS) structure is suitable, but a transistor having another structure, for example, a high voltage MOSFET (HVMOS), a lateral diffusion MOSFET (LDMOS), an insulated gate bipolar transistor (IGBT), a silicon carbide (SiC)-JFET, an SiC-MOSFET, or the like may be used. Other transistors that are not particularly specified as high-voltage elements are MOSFETs having a normal withstand voltage.

The fifth transistor M5 and the sixth transistor M6 are N-channel MOSFETs. The fifth transistor M5 is connected between a drain of the third transistor M3 and a ground line 306. The sixth transistor M6 is connected between a drain of the fourth transistor M4 and the ground line.

The seventh transistor M7 and the eighth transistor M8 are N-channel MOSFETs that are high-voltage elements. The seventh transistor M7 is connected between the first node N1 and the ground line. The eighth transistor M8 is connected between the second node N2 and the ground line. Sizes (gate width to gate length ratio W/L) of the seventh transistor M7 and the eighth transistor M8 are smaller than sizes of the fifth transistor M5 and the sixth transistor M6. In other words, capabilities of the seventh transistor M7 and the eighth transistor M8 are designed to be lower than capabilities of the fifth transistor M5 and the sixth transistor M6.

As an example, when the sizes of the fifth transistor M5 and the sixth transistor M6 are 100, the sizes of the first transistor M1 and the second transistor M2 may be about 20 to 600. Further, the sizes of the seventh transistor M7 and the eighth transistor M8 may be about 5 to 200.

The logic circuit 332 is configured to turn on a pair of the fifth transistor M5 and the seventh transistor M7 when the input signal HIN is at a high level, and turn on a pair of the sixth transistor M6 and the eighth transistor M8 when the input signal HIN is at a low level.

The pulse generator 334 generates a first pulse signal Sp1 and a second pulse signal Sp2 based on the input signal HIN. The first pulse signal Sp1 is a one-shot pulse starting from a positive edge at which the input signal HIN enters a high level from a low level, and the second pulse signal Sp2 is a one-shot pulse starting from a negative edge at which the input signal HIN enters a low level from a high level.

The configuration of the pulse generator 334 is not particularly limited, and it can be configured using a known technique. Instead of inputting the input signal HIN to the pulse generator 334, a gate signal of the fifth transistor M5 and a gate signal of the sixth transistor M6 generated by the logic circuit 332 may be inputted. In this case, the pulse generator 334 may generate, as the first pulse signal Sp1, a one-shot pulse starting from a positive edge of the gate signal of the fifth transistor M5, and generate, as the second pulse signal Sp2, a one-shot pulse starting from a positive edge of the gate signal of the sixth transistor M6.

The first assist circuit 340 is configured to source a first assist current Ia1 to the second node N2 according to the first pulse signal Sp1. Further, the first assist circuit 340 is configured to source a second assist current Ia2 to the first node N1 in response to the second pulse signal Sp2.

The first assist circuit 340 includes a ninth transistor M9 and a tenth transistor M10 that are N-channel MOSFETs being high-voltage elements, and a first current mirror circuit CM1 and a second current mirror circuit CM2 including P-channel MOSFETs. A gate of the ninth transistor M9 is configured to receive the first pulse signal Sp1, and a gate of the tenth transistor M10 is configured to receive the second pulse signal Sp2. The first current mirror circuit CM1 is configured to mirror a current flowing through the ninth transistor M9 to generate the first assist current Ia1. The second current mirror circuit CM2 is configured to mirror a current flowing through the tenth transistor M10 to generate the second assist current Ia2.

When the sizes of the fifth transistor M5 and the sixth transistor M6 are 100, the sizes of the ninth transistor M9 and the tenth transistor M10 may be about 30 to 100.

The configuration of the driver circuit 300 has been described above. Next, an operation of the driver circuit 300 will be described.

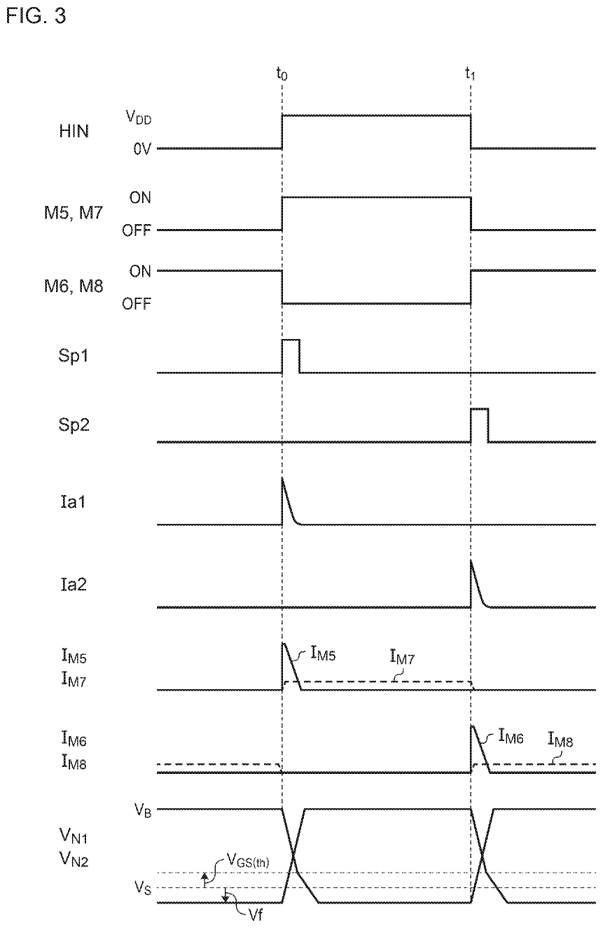

FIG. 3 is an operation waveform diagram of the driver circuit 300 of FIG. 2. FIG. 3 shows the input signal HIN, the states of the transistors M5 and M7, the states of the transistors M6 and M8, the first pulse signal Sp1, the second pulse signal Sp2, the first assist current Ia1, the second assist current Ia2, a current I_{M5} flowing through the fifth transistor M5, a current I_{M7} flowing through the seventh transistor M7, a current I_{M6} flowing through the sixth transistor M6, a current I_{M8} flowing through the eighth transistor M8, the voltage V_{N1} of the first node N1, and the voltage V_{N2} of the second node N2.

Note that the waveforms of the voltage V_{N1} of the first node N1 and the voltage V_{N2} of the second node N2 are drawn with the switching voltage V_{S} as a reference. It should be noted that, in practice, the switching voltage V_{S} switches between 0 V and V_{IN}.

At time t₀, the input signal HIN enters a high level from a low level. In response to this transition, the logic circuit 332 turns on the fifth transistor M5 and the seventh transistor M7. As the fifth transistor M5 is turned on, the current I_{M5} is drawn from the first node N1 via the third transistor M3 and the fifth transistor M5. The potential V_{N1} of the first node N1 decreases due to the current I_{M5}. At this time, since the seventh transistor M7 is also turned on, the current I_{M7} also flows through the seventh transistor M7. However, since the capability of the seventh transistor M7 is lower than the capability of the fifth transistor M5, it can be said that the capability to lower the potential V_{N1} of the first node N1 is low.

When the potential of the first node N1 decreases to V_{S}+V_{GS(th)}, the third transistor M3 is turned off, and thus the current I_{M5} flowing through the fifth transistor M5 becomes substantially zero.

A parasitic capacitance of the fourth transistor M4 exists at the second node N2. In order to cause the latch circuit 331 to enter a state transition, it is necessary to invert a magnitude relationship between the voltages V_{N1} and V_{N2} of the two nodes. Here, the parasitic capacitance of the fourth transistor M4 prevents a rise in the voltage V_{N2}. The pulse generator 334 generates the first pulse signal Sp1 in response to a positive edge of the input signal HIN at time t₀. In response to the first pulse signal Sp1, the ninth transistor M9 is turned on, and a pulsed first assist current Ia1 is supplied to the second node N2. The first assist current Ia1 increases the potential V_{N2} of the second node N2 by charging the parasitic capacitance of the fourth transistor M4. That is, the first assist current Ia1 accelerates the transition of the latch circuit 331 including the first transistor M1 and the second transistor M2.

After the state transition of the latch circuit 331, even after the third transistor M3 is turned off, the seventh transistor M7 maintains an on-state. By a minute current I_{M7} flowing through the seventh transistor M7, charge is drawn from the first node N1, and the potential V_{N1} of t he first node N1 decreases to a voltage level lower than V_{S}+V_{GS(th)}. When the potential V_{N1} of the first node N1 decreases to V_{S}−Vf, the potential V_{N1} of the first node N1 is clamped by a diode D3. Vf is a forward voltage of the diode D4.

At time t₁, the input signal HIN enters a low level from a high level. In response to this transition, the logic circuit 332 turns on the sixth transistor M6 and the eighth transistor M8. As the sixth transistor M6 is turned on, the current I_{M6} is drawn from the second node N2 via the fourth transistor M4 and the sixth transistor M6. The potential V_{N2} of the second node N2 decreases due to the current I_{M6}. At this time, since the eighth transistor M8 is also turned on, the current I_{M8} also flows through the eighth transistor M8. But since the capability of the eighth transistor M8 is lower than the capability of the sixth transistor M6, it can be said that the capability to lower the potential V_{N2} of the second node N2 is low.

When the potential of the second node N2 decreases to V_{S}+V_{GS(th)}, the fourth transistor M4 is turned off, and thus the current I_{M6} flowing through the sixth transistor M6 becomes substantially zero.

A parasitic capacitance of the third transistor M3 also exists at the first node N1, and this parasitic capacitance prevents a rise in the voltage V_{N1}. The pulse generator 334 generates the second pulse signal Sp2 in response to a negative edge of the input signal HIN at time t₁. In response to the second pulse signal Sp2, the tenth transistor M10 is turned on, and a pulsed second assist current Ia2 is supplied to the first node N1. The second assist current Ia2 increases the potential V_{N1} of the first node N1 by charging the parasitic capacitance of the third transistor M3. That is, the second assist current Ia2 accelerates the transition of the latch circuit 331 including the first transistor M1 and the second transistor M2.

After the state transition of the latch circuit 331, even after the fourth transistor M4 is turned off, the eighth transistor M8 maintains an on-state. By a minute current I_{M8} flowing through the eighth transistor M8, charge is drawn from the second node N2, and the potential V_{N2} of the second node N2 decreases to a voltage level lower than V_{S}+V_{GS(th)}. When the potential V_{N2} of the second node N2 decreases to V_{S}−Vf, the potential V_{N2} of the second node N2 is clamped by a diode D4. Vf is a forward voltage of the diode D3.

The operation of the driver circuit 300 has been described above. According to this driver circuit 300, by injecting the assist currents Ia1 and Ia2 into the first node N1 or the second node N2 by the first assist circuit 340, the state transition of the latch circuit 331 can be accelerated. Thereby, the level shift circuit 330 can transmit the input signal HIN to the high-side driver 310 at high speed.

In this driver circuit 300, when the input signal HIN is at a high level, even after the third transistor M3 is turned off, a current can be drawn from the first node N1 toward the ground via the seventh transistor M7. Thereby, the voltage V_{N1} of the first node N1 can be lowered to near the voltage V_{S} of the switching line, specifically, to V_{S}−Vf. Similarly, when the input signal HIN is at a low level, even after the fourth transistor M4 is turned off, a current can be drawn from the second node N2 toward the ground via the eighth transistor M8. Thereby, the voltage V_{N2} of the second node N2 can be lowered to near the voltage V_{S} of the switching line. Thereby, amplitudes of output signals generated at the first node and the second node can be widened, and stability of the circuit when a potential difference between the bootstrap line 302 and the switching line 304 becomes small can be enhanced.

Next, modifications of the level shift circuit 330 will be described.

### MODIFICATION 1

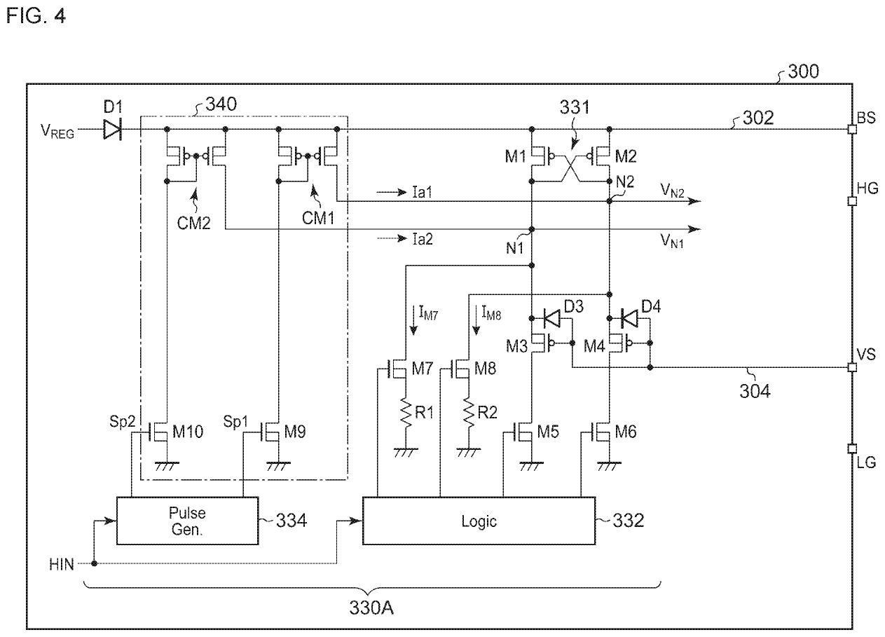

FIG. 4 is a circuit diagram of a level shift circuit 330A according to Modification 1. The level shift circuit 330A includes a first resistor R1 and a second resistor R2 in addition to the level shift circuit 330 of FIG. 2. The first resistor R1 is connected in series with the seventh transistor M7 between the first node N1 and the ground line 306. The second resistor R2 is connected in series with the eighth transistor M8 between the second node N2 and the ground line 306.

By the first resistor R1 and the second resistor R2, an amount of steady-state currents I_{M7} and I_{M8} flowing via the seventh transistor M7 and the eighth transistor M8 can be reduced, and a decrease in efficiency can be suppressed.

### MODIFICATION 2

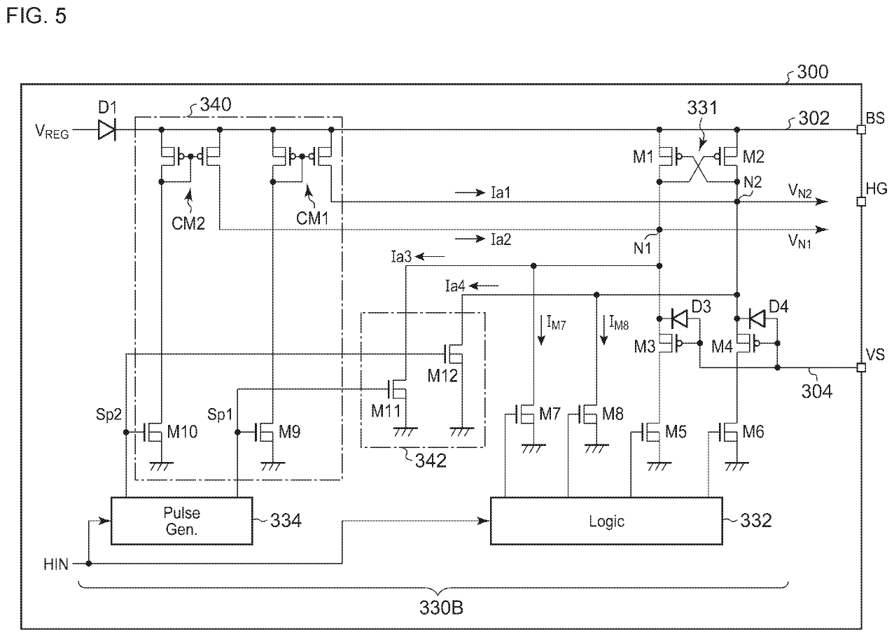

FIG. 5 is a circuit diagram of a level shift circuit 330B according to Modification 2. The level shift circuit 330B has a configuration in which a second assist circuit 342 is added to the level shift circuit 330 of FIG. 2.

The second assist circuit 342 is configured to sink a third assist current Ia3 from the first node N1 in accordance with the first pulse signal Sp1, and sink a fourth assist current Ia4 from the second node N2 in response to the second pulse signal Sp2.

The second assist circuit 342 includes an eleventh transistor M11 and a twelfth transistor M12 that are N-channel MOSFETs being high-voltage elements. The eleventh transistor M11 has a gate configured to receive the first pulse signal Sp1 and a drain connected to the first node N1. The twelfth transistor M12 has a gate configured to receive the second pulse signal Sp2 and a drain connected to the second node N2.

When the sizes of the fifth transistor M5 and the sixth transistor M6 are 100, the sizes of the eleventh transistor M11 and the twelfth transistor M12 may be about 30 to 100.

The configuration of the level shift circuit 330B has been described above. According to this level shift circuit 330B, immediately after the input signal HIN enters a high level from a low level, a potential V_{N1} of the first node N1 decreases due to a third assist current Ia3 flowing through the eleventh transistor M11 in addition to a current I_{M5} flowing through the fifth transistor M5. Thereby, the transition of the latch circuit 331 can be accelerated.

Similarly, immediately after the input signal HIN enters a low level from a high level, a potential V_{N2} of the second node N2 decreases due to a fourth assist current Ia4 flowing through the twelfth transistor M12 in addition to a current I_{M6} flowing through the sixth transistor M6. Thereby, the transition of the latch circuit 331 can be accelerated.

When a potential difference V_{B}−V_{S} between the bootstrap line 302 and the switching line 304 decreases, that is, when the DC voltage V_{REG} decreases (referred to as an under-voltage state), drain-to-source voltages of transistors in the current mirror circuits CM1 and CM2 of the first assist circuit 340 become small. Therefore, an operation speed of the first assist circuit 340 becomes slow, and a delay time of the level shift circuit 330 may become long. On the other hand, it can be said that the second assist circuit 342 is less susceptible to a decrease in the voltage V_{B} of the bootstrap line 302. Therefore, by providing the second assist circuit 342, an increase in the delay time of the level shift circuit 330B in the under-voltage state can be suppressed.

Note that the second assist circuit 342 may be added to the level shift circuit 330A of Modification 1.

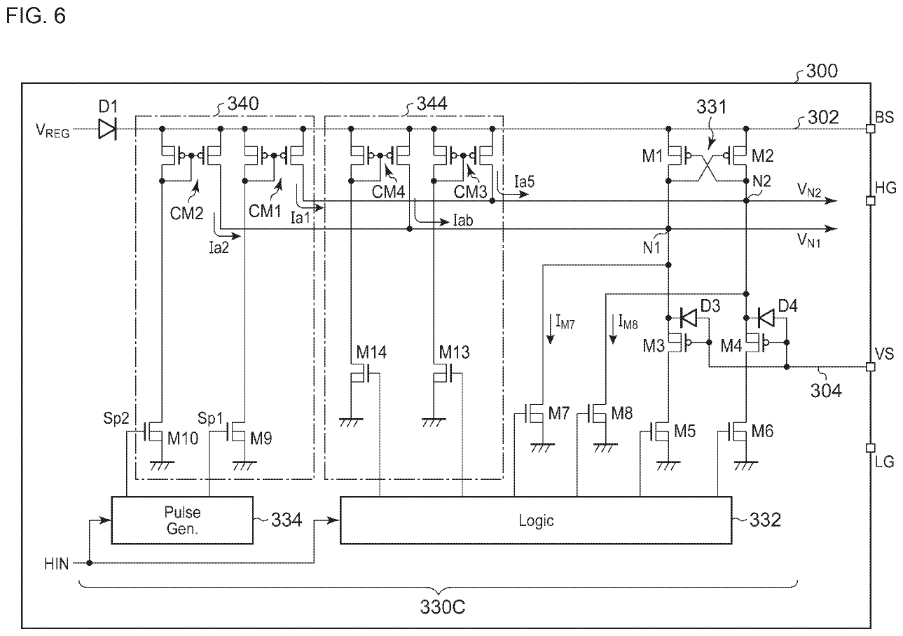

FIG. 6 is a circuit diagram of a level shift circuit 330C according to Modification 3. The level shift circuit 330C has a configuration in which a third assist circuit 344 is added to the level shift circuit 330 of FIG. 2. The third assist circuit 344 is configured to source a fifth assist current Ia5 to the second node N2 when the input signal HIN is at a high level, and source a sixth assist current Ia6 to the first node N1 when the input signal HIN is at a low level.

The third assist circuit 344 may include a thirteenth transistor M13, a fourteenth transistor M14, a third current mirror circuit CM3, and a fourth current mirror circuit CM4. The thirteenth transistor M13 and the fourteenth transistor M14 are N-channel MOSFETs that are high-voltage elements, and are controlled by the logic circuit 332. The thirteenth transistor M13 is turned on when the input signal HIN is at a high level. The fourteenth transistor M14 is turned on when the input signal HIN is at a low level. The third current mirror circuit CM3 is configured to mirror a current flowing through the thirteenth transistor M13 to generate the fifth assist current Ia5. The fourth current mirror circuit CM4 is configured to mirror a current flowing through the fourteenth transistor M14 to generate the sixth assist current Ia6.

It is desirable that sizes (current supply capabilities) of the thirteenth transistor M13 and the fourteenth transistor M14 are designed to be smaller than sizes of the ninth transistor M9 and the tenth transistor M10. When the sizes of the fifth transistor M5 and the sixth transistor M6 are 100, the sizes of the ninth transistor M9 and the tenth transistor M10 can be about 30 to 100, and the sizes of the thirteenth transistor M13 and the fourteenth transistor M14 can be about 0.1 to 5.

Similarly to the resistors R1 and R2 of FIG. 4, also in FIG. 6, a current limiting resistor may be inserted in series with each of the thirteenth transistor M13 and the fourteenth transistor M14.

The configuration of the level shift circuit 330C has been described above. Next, an operation thereof will be described.

In FIG. 2, when a state of the latch circuit 331 is inverted due to influence of switching noise or a parasitic element, the latch circuit 331 maintains the inverted state until the next switching cycle, and thus the high-side transistor MH is driven in an incorrect state. In order to solve this problem, it is necessary to increase driving capabilities of the seventh transistor M7 and the eighth transistor M8. However, when they are configured by DMOS transistors, it is necessary to increase an element size in order to increase the driving capabilities. On the other hand, in the level shift circuit 330C of FIG. 6, by adding the third assist circuit 344, an increase in the sizes of the seventh transistor M7 and the eighth transistor M8 can be suppressed, and the latch circuit 331 can be restored from the erroneously inverted state to a correct state.

### APPLICATION

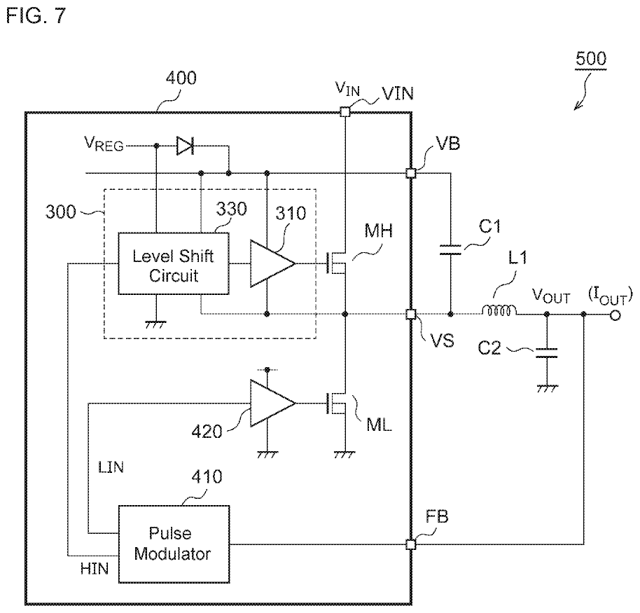

Next, applications of the driver circuit 300 will be described. The driver circuit 300 can be used for a DC/DC converter. FIG. 7 is a circuit diagram of a controller circuit 400 of a DC/DC converter 500. The DC/DC converter 500 is a synchronous rectification buck converter, and includes capacitors C1 and C2 and an inductor L1 in addition to the controller circuit 400.

The controller circuit 400 includes a high-side transistor MH, a low-side transistor ML, a pulse modulator 410, a low-side driver circuit 420, and a driver circuit (high-side driver circuit) 300. The pulse modulator 410 generates pulse signals HIN and LIN such that an output (an output voltage, an output current, or a state of a load) of the DC/DC converter 500 approaches a target. For example, the pulse modulator 410 may cause the output voltage V_{OUT} to approach a target voltage VREF (constant voltage control), or may cause the output current I_{OUT} to approach a target current I_{REF} (constant current control).

The high-side driver circuit 300 drives an N-channel or NPN high-side transistor MH based on the pulse signal HIN. Further, the low-side driver circuit 420 drives a low-side transistor ML based on the pulse signal LIN.

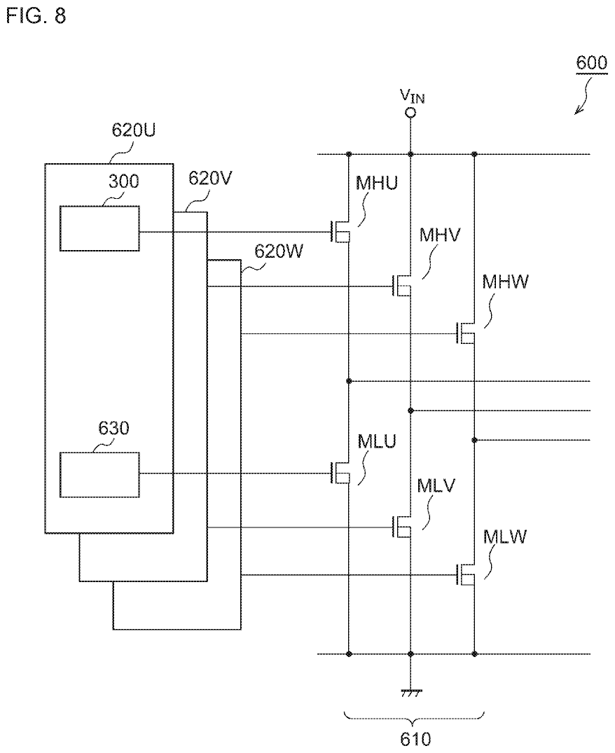

The driver circuit 300 can be used for an inverter apparatus. FIG. 8 is a circuit diagram of an inverter apparatus 600 including the driver circuit 300. The inverter apparatus 600 includes a three-phase inverter 610, and U-phase, V-phase, and W-phase driver circuits 620U, 620V, and 620W. The three-phase inverter 610 includes high-side transistors MHU, MHV, and MHW, and low-side transistors MLU, MLV, and MLW. A driver circuit 620 #(#=U, V, W) includes the high-side driver circuit 300 and a low-side driver circuit 630.

The embodiments have been described above. These embodiments are illustrative, and those skilled in the art understand that various modifications can be made to combinations of the respective constituent elements and the respective processing processes, and such modifications are also within the scope of the present disclosure. Hereinafter, such modifications will be described.

In the embodiments, the high-side transistor MH has been described as an N-channel MOSFET, but it may be an NPN bipolar transistor or an IGBT. In this case, the gate, source, and drain may be read as a base, an emitter, and a drain.

In the embodiments, the high-side transistor MH is a discrete component externally connected to the IC of the driver circuit 300, but the high-side transistor MH may be integrated on the same semiconductor substrate (chip) as the driver circuit 300.

In the DC/DC converter 500 of FIG. 7, the low-side transistor ML may be replaced with a diode. Further, the topology of the DC/DC converter 500 is not limited to a buck type, and may be another type provided with a high-side transistor.

Applications of the switching circuit 100 are not limited to DC/DC converters and inverter apparatuses. For example, the switching circuit 100 is also applicable to a bidirectional converter, a battery charging circuit, and a class-D amplifier for audio.

The embodiments merely show the principles and applications of the present disclosure, and many modifications and changes in arrangement are permitted in the embodiments within a scope that does not depart from the spirit of the present disclosure defined in the claims.

### SUPPLEMENTARY NOTES

The technology disclosed in the present specification can be understood as follows in one aspect.

Item 1. A driver circuit for driving an N-type high-side transistor connected between an input line and a switching line, the driver circuit comprising:
a level shift circuit configured to level-shift an input signal; and
a high-side driver configured to drive the high-side transistor according to an output of the level shift circuit,
wherein the level shift circuit includes:
   a P-type first transistor connected between a bootstrap line and a first node;
   a P-type second transistor connected between the bootstrap line and a second node, the P-type second transistor being cross-coupled with the first transistor;
   a P-type third transistor that is a high-voltage element, having a gate connected to the switching line and a source connected to the first node;
   a P-type fourth transistor that is a high-voltage element, having a gate connected to the switching line and a source connected to the second node;
   an N-type fifth transistor connected between a drain of the third transistor and a ground line;
   an N-type sixth transistor connected between a drain of the fourth transistor and the ground line;
   an N-type seventh transistor that is a high-voltage element connected between the first node and the ground line;
   an N-type eighth transistor that is a high-voltage element connected between the second node and the ground line;
   a logic circuit configured (i) to turn on a pair of the fifth transistor and the seventh transistor when the input signal is at a high level, and (ii) to turn on a pair of the sixth transistor and the eighth transistor when the input signal is at a low level; and
   a first assist circuit configured (i) to source a first assist current to the second node in accordance with a first pulse signal based on a positive edge of the input signal entering the high level from the low level, and (ii) to source a second assist current to the first node in response to a second pulse signal based on a negative edge of the input signal entering the low level from the high level.

Item 2. The driver circuit according to item 1, wherein the level shift circuit further includes:
a first resistor connected in series with the seventh transistor between the first node and the ground line; and
a second resistor connected in series with the eighth transistor between the second node and the ground line.

Item 3. The driver circuit according to item 1 or 2, wherein the first assist circuit includes:
an N-type ninth transistor that is a high-voltage element, having a gate configured to receive the first pulse signal;
an N-type tenth transistor that is a high-voltage element, having a gate configured to receive the second pulse signal;
a first current mirror circuit configured to mirror a current flowing through the ninth transistor to generate the first assist current; and
a second current mirror circuit configured to mirror a current flowing through the tenth transistor to generate the second assist current.

Item 4. The driver circuit according to any one of items 1 to 3, wherein the level shift circuit further includes a second assist circuit configured (i) to sink a third assist current from the first node in accordance with the first pulse signal, and (ii) to sink a fourth assist current from the second node in response to the second pulse signal.

Item 5. The driver circuit according to item 4, wherein the second assist circuit includes:
an N-type eleventh transistor that is a high-voltage element, having a gate configured to receive the first pulse signal and a drain connected to the first node; and
an N-type twelfth transistor that is a high-voltage element, having a gate configured to receive the second pulse signal and a drain connected to the second node.

Item 6. The driver circuit according to any one of items 1 to 5, wherein the level shift circuit further includes a third assist circuit configured (i) to source a fifth assist current to the second node when the input signal is at the high level, and (ii) to source a sixth assist current to the first node when the input signal is at the low level.

Item 7. The driver circuit according to item 6, wherein the third assist circuit includes:
an N-type thirteenth transistor that is a high-voltage element configured to turn on when the input signal is at the high level;
an N-type fourteenth transistor that is a high-voltage element configured to turn on when the input signal is at the low level;
a third current mirror circuit configured to mirror a current flowing through the thirteenth transistor to generate the fifth assist current; and
a fourth current mirror circuit configured to mirror a current flowing through the fourteenth transistor to generate the sixth assist current.

Item 8. A switching circuit comprising:
a high-side transistor provided between an input line and a switching line;
a low-side transistor provided between the switching line and a ground line; and
the driver circuit according to any one of items 1 to 7 configured to drive the high-side transistor.

Item 9. A controller circuit for a DC/DC converter, the controller circuit comprising:
a pulse modulator configured to generate a pulse signal such that an output of the DC/DC converter approaches a target; and
the driver circuit according to any one of items 1 to 7 configured to drive an N-type high-side transistor based on the pulse signal.

What is claimed is:

1. A driver circuit for driving an N-type high-side transistor connected between an input line and a switching line, the driver circuit comprising:
a level shift circuit configured to level-shift an input signal; and
a high-side driver configured to drive the high-side transistor according to an output of the level shift circuit,
wherein the level shift circuit includes:
a P-type first transistor connected between a bootstrap line and a first node;
a P-type second transistor connected between the bootstrap line and a second node, the P-type second transistor being cross-coupled with the first transistor;
a P-type third transistor that is a high-voltage element, having a gate connected to the switching line and a source connected to the first node;
a P-type fourth transistor that is a high-voltage element, having a gate connected to the switching line and a source connected to the second node;
an N-type fifth transistor connected between a drain of the third transistor and a ground line;
an N-type sixth transistor connected between a drain of the fourth transistor and the ground line;
an N-type seventh transistor that is a high-voltage element connected between the first node and the ground line;
an N-type eighth transistor that is a high-voltage element connected between the second node and the ground line;
a logic circuit configured (i) to turn on a pair of the fifth transistor and the seventh transistor when the input signal is at a high level, and (ii) to turn on a pair of the sixth transistor and the eighth transistor when the input signal is at a low level; and
a first assist circuit configured (i) to source a first assist current to the second node in accordance with a first pulse signal based on a positive edge of the input signal entering the high level from the low level, and (ii) to source a second assist current to the first node in response to a second pulse signal based on a negative edge of the input signal entering the low level from the high level.

2. The driver circuit according to claim 1, wherein the level shift circuit further includes:
a first resistor connected in series with the seventh transistor between the first node and the ground line; and
a second resistor connected in series with the eighth transistor between the second node and the ground line.

3. The driver circuit according to claim 1, wherein the first assist circuit includes:
an N-type ninth transistor that is a high-voltage element, having a gate configured to receive the first pulse signal;
an N-type tenth transistor that is a high-voltage element, having a gate configured to receive the second pulse signal;
a first current mirror circuit configured to mirror a current flowing through the ninth transistor to generate the first assist current; and
a second current mirror circuit configured to mirror a current flowing through the tenth transistor to generate the second assist current.

4. The driver circuit according to claim 1, wherein the level shift circuit further includes a second assist circuit configured (i) to sink a third assist current from the first node in accordance with the first pulse signal, and (ii) to sink a fourth assist current from the second node in response to the second pulse signal.

5. The driver circuit according to claim 4, wherein the second assist circuit includes:
an N-type eleventh transistor that is a high-voltage element, having a gate configured to receive the first pulse signal and a drain connected to the first node; and
an N-type twelfth transistor that is a high-voltage element, having a gate configured to receive the second pulse signal and a drain connected to the second node.

6. The driver circuit according to claim 1, wherein the level shift circuit further includes a third assist circuit configured (i) to source a fifth assist current to the second node when the input signal is at the high level, and (ii) to source a sixth assist current to the first node when the input signal is at the low level.

7. The driver circuit according to claim 6, wherein the third assist circuit includes:
an N-type thirteenth transistor that is a high-voltage element configured to turn on when the input signal is at the high level;
an N-type fourteenth transistor that is a high-voltage element configured to turn on when the input signal is at the low level;
a third current mirror circuit configured to mirror a current flowing through the thirteenth transistor to generate the fifth assist current; and
a fourth current mirror circuit configured to mirror a current flowing through the fourteenth transistor to generate the sixth assist current.

8. A switching circuit comprising:
a high-side transistor provided between an input line and a switching line;
a low-side transistor provided between the switching line and a ground line; and
the driver circuit according to claim 1 configured to drive the high-side transistor.

9. A controller circuit for a DC/DC converter, the controller circuit comprising:
a pulse modulator configured to generate a pulse signal such that an output of the DC/DC converter approaches a target; and
the driver circuit according to claim 1 configured to drive an N-type high-side transistor based on the pulse signal.
